(19) United States
(12) Patent Application Publication
(10) Pub. No.: US 2008/0233672 A1
(43) Pub. Date: Sep. 25, 2008

(54) METHOD OF INTEGRATING MEMS STRUCTURES AND CMOS STRUCTURES USING OXIDE FUSION BONDING

(75) Inventor: John Heck, Berkeley, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 11/688,808

(22) Filed: Mar. 20, 2007

(51) Int. Cl. H01L 21/00

(52) U.S. Cl. 438/48; 257/E21.001

(57) ABSTRACT

A method to fabricate a device including a micro-electro-mechanical system structure and a monolithic integrated circuit comprises using a first wafer as a first substrate, fabricating the micro-electro-mechanical system structure on the first substrate, and forming a first oxide layer over the micro-electro-mechanical system structure. The method further comprises using a second wafer as a second substrate, fabricating the monolithic integrated circuit on the second substrate, and forming a second oxide layer over the monolithic integrated circuit. The first wafer and the second wafer are arranged so that the first oxide layer opposes the second oxide layer. The micro-electro-mechanical system structure is aligned with the monolithic integrated circuit, the first oxide layer is contacted with the second oxide layer; and bonded with the second oxide layer.

### TECHNICAL FIELD

This invention relates to integration of micro-electro-mechanical systems and monolithic integrated circuits.

### BACKGROUND

Software developers continue to develop steadily more data intensive products, such as ever-more sophisticated, and graphic intensive applications and operating systems (OS). Higher capacity data storage, both volatile and non-volatile, has been in persistent demand for storing code for such applications. Add to this need for capacity, the confluence of personal computing and consumer electronics in the form of personal MP3 players, such as iPod®, personal digital assistants (PDAs), sophisticated mobile phones, and laptop computers, which has placed a premium on compactness and reliability.

Nearly every personal computer and server in use today contains one or more hard disk drives for permanently storing frequently accessed data. Every mainframe and supercomputer is connected to hundreds of hard disk drives. Consumer electronic goods ranging from camcorders to TiVo® use hard disk drives. While hard disk drives store large amounts of data, they consume a great deal of power, require long access times, and require “spin-up” time on power-up. FLASH memory is a more readily accessible form of data storage and a solid-state solution to the lag time and high power consumption problems inherent in hard disk drives. Like hard disk drives, FLASH memory can store data in a non-volatile fashion, but the cost per megabyte is dramatically higher than the cost per megabyte of an equivalent amount of space on a hard disk drive, and is therefore sparingly used. Solutions are forthcoming which permit higher density data storage at a reasonable cost per megabyte.

One such solution is probe storage which employs MEMS-based probe tips to form hysteretic domains in media. Myriad different media have been proposed, as have probe storage devices wherein one or both of the probe tips and the media is moved to allow the probe tips to access multiple domains. Integrating structures manufactured using multiple different techniques can pose a challenge. Consequently, there is a need for solutions which facilitate wedding MEMS-based structures with myriad different media.

### BRIEF DESCRIPTION OF THE DRAWINGS

Further details of the present invention are explained with the help of the attached drawings in which:

FIG. 1 is a cross-sectional view of a system for storing information.

FIGS. 2A-2G are film stack cross-sections of a cantilever and tip assembly wafer in progressive steps of processing; FIG. 2H is a film stack cross-section of a cantilever and tip assembly wafer bondable with a complementary circuitry wafer.

FIGS. 3A-3H are film stack cross-sections of the cantilever and tip assembly wafer and circuitry wafer in progressive steps of processing to form a tip die.

### DETAILED DESCRIPTION

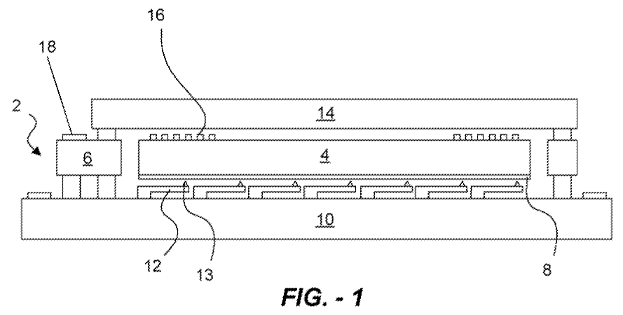

Systems and methods for storing information using probe tips in electrical communication with a media can enable higher density data storage relative to popular magnetic and solid state storage technology. Referring to FIG. 1, such a system and method can include a tip die 10 arranged parallel to a media 8 disposed on a media platform 4. Cantilevers 12 can extend from the tip die 10, and probe tips 13 (also referred to herein simply as tips) extend from respective cantilevers 12 toward the surface of the media 8. The tips 13 are used as read-write heads and the media 8 and tip die 10 are urged with respect to each other to allow scanning of the media 8 by the tips 13 and data transfer between the tips 13 and the media 8. The number of tips 13 in electrical communication with the media 8 or connectable with the media 8 is defined by a desired goal of the architecture. For example, to increase a data transfer rate of the system 1, a relatively large number of tips 13 can be employed operating in parallel. Alternatively, where system 1 complexity is a concern, the number of tips 13 can be relatively small to reduce an amount of circuitry associated with the tips 13.

The tips 13 are made sharp (20-100 nm diameter) to reduce the size of an indicia formed within the media 8 representing information such as a bit. The media 8 can include a storage layer comprising a phase change material (e.g., chalcogenide), ferroelectric material, ferromagnetic material, polymer material, and/or some other material known in probe-storage literature.

In the system shown in FIG. 1, the media platform 4 is movable within a frame 6, with the frame 6 and media platform 4 comprising a media die 2. The media platform 4 can be movable within the frame 6 by way of thermal actuators, piezoelectric actuators, voice coil motors, etc. The media die 2 can be bonded with the tip die 10 and a cap die 14 can be bonded with the media die 2 to seal the media platform 4 within a cavity.

Wiring the servo and channel electronics associated with the tips can require that the electronics be integrated into the tip die. Integration can improve bandwidth. Further, integration allows electrical amplifiers to be arranged adjacent to the cantilever/tip assembly to improve a signal-to-noise ratio for read/write/erase operations on the media. A desirable architecture can employ complementary metal-oxide semiconductor (CMOS) circuitry for servo and channel electronics. However, directly fabricating cantilevers and tips onto CMOS circuitry presents significant challenges because CMOS structures cannot tolerate the high thermal budget required for some processes preferred in fabricating cantilevers and/or tips (e.g., diffusion or oxidation). Embodiments of systems and methods to fabricate tip die in accordance with the present invention include integrating the cantilever and tip structures onto CMOS circuitry by transferring the cantilever and tip structures from a donor wafer. Transferring fabricated cantilevers and tip structures from a donor wafer to a wafer including fabricated circuitry can provide the advantage of decoupling the processes for forming the incompatible structures. The processes for forming the CMOS circuitry and the processes for forming the cantilever and tip structures are thereby independently optimizable.

Current transfer approaches for integrating micro-electro-mechanical system (MEMS) structures such as cantilevers and tips with CMOS devices include using metallic bonding techniques. However, metallic bonding techniques introduce unwanted translation and/or rotation of MEMS structures relative to the CMOS devices due to the malleable nature of the bonds and/or reflowing during the bonding process. Further, some approaches use two-stage transfer in which the devices are fabricated on a “donor” wafer, transferred to a “carrier” wafer, and finally transferred to a CMOS wafer. Embodiments of methods to join MEMS structures and semiconductor circuitry in accordance with the present invention can employ oxide fusion bonding to improve alignment and flatness of the transferred structures. Such embodiments include a transfer process comprising fabricating the cantilever and tip structures on a “donor” wafer and transferring the cantilever and tip structures to a CMOS circuitry wafer. Using a one transfer process can reduce propagation of error which can result in or contribute to higher yield and lower cost. While embodiments of methods in accordance with the present invention will be described with particular reference to tip die including cantilevers and tips bonded with CMOS circuitry, it should be understood that such techniques could alternatively be used with MEMS structures other than cantilevers and tips bonded to a monolithic integrated circuit based on alternative technology.

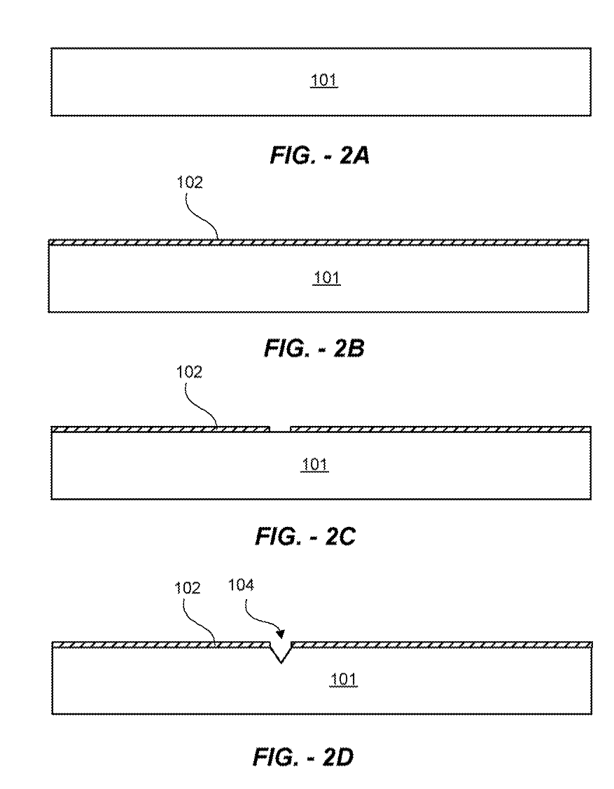

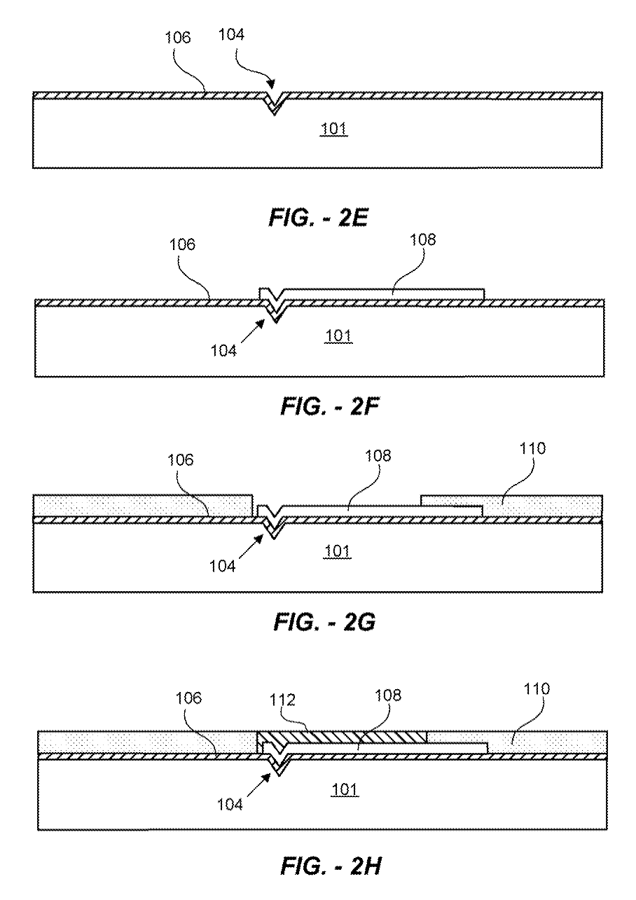

Referring to FIGS. 2A-2H, the cantilever and tip structures can be fabricated in a tip-first approach that will be referred to herein as “inverted.” As shown, a silicon substrate 101 is used to serve as a mold for forming the tip. The silicon substrate 101 is thermally oxidized to form a thin mask layer 102 (FIGS. 2A and 2B). The silicon dioxide (SiO2) mask layer 102 can then be patterned and etched by way of wet or dry etching (FIG. 2C) to form a mask to define the tip. Mask layer 102 can alternatively be silicon nitride (SiₓN_{y}) Preferably, the mask will have a square shape, which during subsequent processing will cause an approximately conically shaped mold to form within the silicon substrate. However, in other embodiments, the mask can have a shape other than square. The silicon substrate 101 is then etched to form the tip mold 104 using potassium hydroxide (KOH), ethylene diamine pyrocatechol (EDP), or some other etchant having good selectivity to silicon dioxide and that etches along a desired crystallographic direction (FIG. 2D). The silicon substrate 101 is thermally oxidized again to sharpen the mold 104 and create a silicon dioxide barrier layer 106 between the cantilever and tip structures to be formed and the silicon substrate 101 (FIG. 2E). A polysilicon layer 107 is then deposited or otherwise formed over the surface including within the mold 104. The polysilicon layer 107 is patterned and etched to define a cantilever 108 (FIG. 2F). Layer 107 can alternatively be another material such as silicon carbide, silicon nitride, polycrystalline diamond, etc. An oxide bonding layer 110 is then deposited or formed over the surface of the wafer, the oxide bonding layer 110 providing a bonding surface (FIG. 2G). The oxide bonding layer 110 can comprise silicon dioxide, or an alternative suitable bonding film. For example, a doped silicon dioxide, such as borophosphosilicate glass (BPSG) or spin on glass (SOG). The oxide bonding layer 110 is patterned so that a portion of the oxide bonding layer 110 overlaps a proximal end of the cantilever 108, while a distal end of the cantilever 108 including the tip is exposed. A sacrificial layer 112 (e.g., copper) is deposited over the wafer so that the exposed cantilever and tip structures 108 are enveloped. The cantilever/tip assembly wafer 100 is finally planarized, for example by chemical mechanical polishing (CMP) (FIG. 2H). The sacrificial layer 112 can be chosen based on a number of factors including ease of planarizing, durability during a bonding process, and ease of removal during subsequent processing.

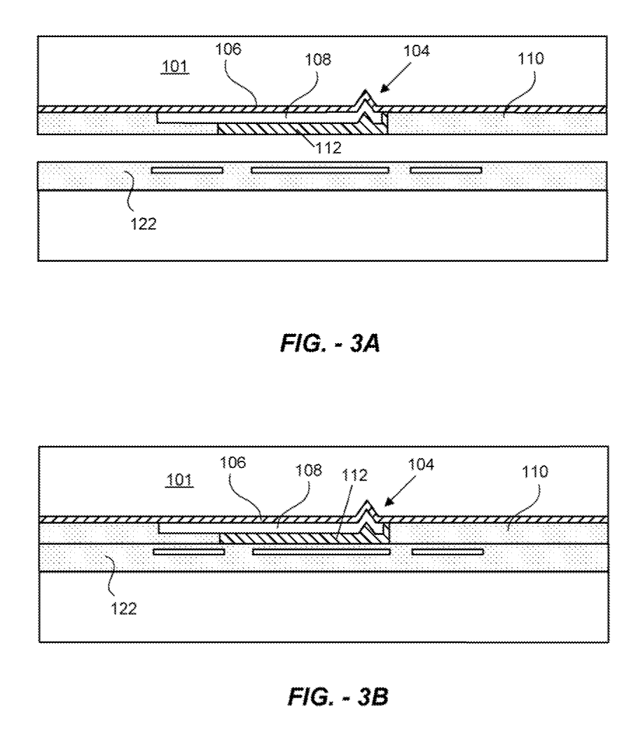

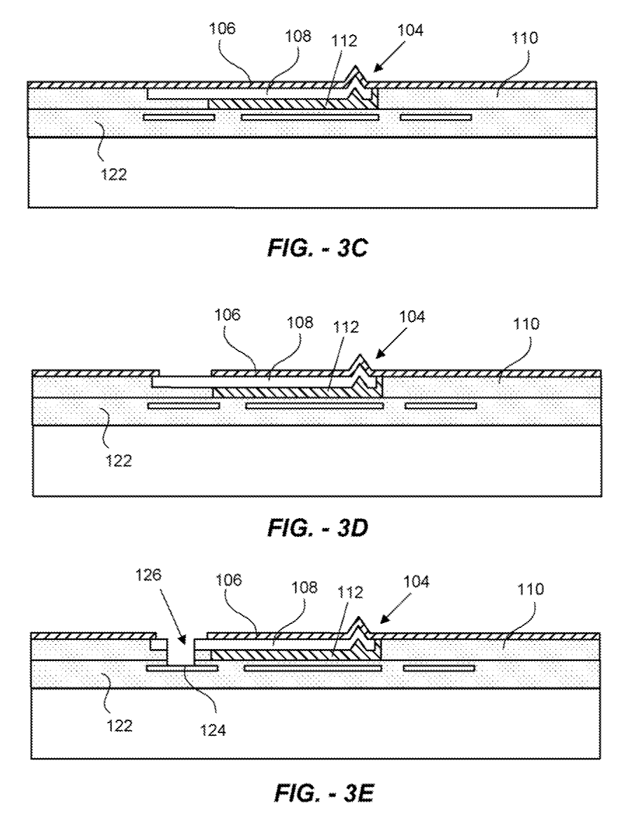

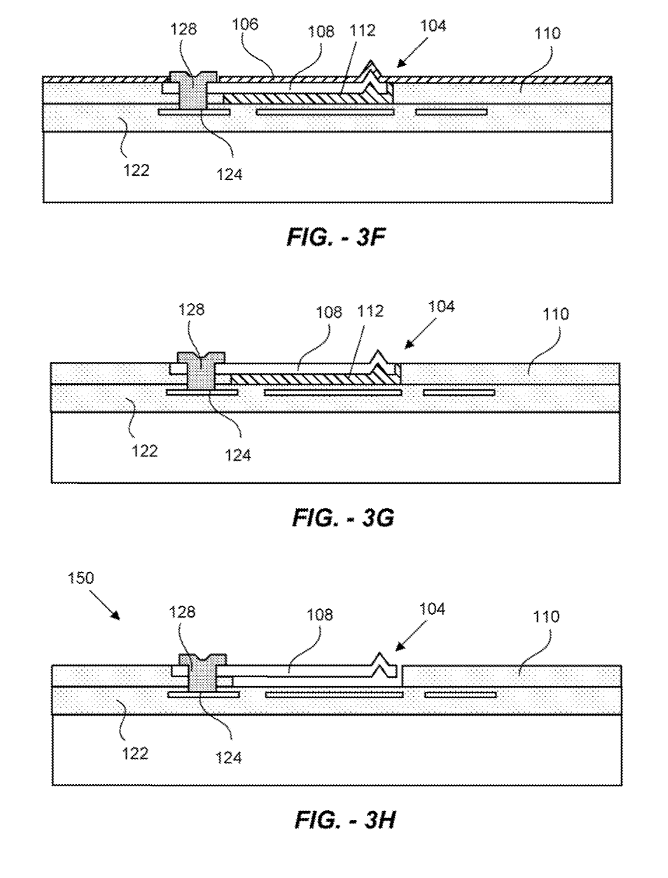

The CMOS circuitry associated with the cantilever and tip structures 108 can be fabricated through a series of CMOS semiconductor processing steps. One of ordinary skill in the art will appreciate and have command of knowledge for fabricating circuitry by way of CMOS semiconductor processing. Because the circuitry is fabricated using typical CMOS processing methods rather than metal bonding, many contacts can be arranged within a small area to improve routing. Referring to FIGS. 3A-3H, the CMOS wafer 120 will additionally have a thin oxide bonding layer 122 providing a bonding surface. The bonding layer 122 should be planarized to enable good contact with the bonding surface of the cantilever/tip assembly wafer 100. The planarized cantilever/tip assembly wafer 100 is aligned (FIG. 3A) and bonded to the CMOS wafer 120 by causing a low-temperature oxide fusion bond (FIG. 3B) between the bonding layers 112,120. The oxide fusion bond can be achieved at temperatures below 400° C. and as low as room temperature using plasma activation.

The silicon substrate 101 is removed from the cantilever/tip assembly wafer 100 after the cantilever/tip assembly wafer 100 is bonded with the CMOS wafer 120. The silicon substrate 101 can be removed by wet etching, plasma etching, grinding, or a combination thereof With the silicon substrate removed, the silicon dioxide barrier layer 106 is exposed to processing (FIG. 3C). The silicon dioxide barrier layer 106 is patterned and etched to expose polysilicon at a proximal end of the cantilever 108 (FIG. 3D). The polysilicon is patterned and the film stack is etched until an appropriate conductive interconnect 124 of the CMOS wafer 120 is exposed, thereby forming a via 126 (FIG. 3E). A conductive film such as aluminum or copper is then deposited, patterned, and etched, thereby forming discrete electrical connection between the cantilever 108 and the exposed conductive interconnect 124 of the CMOS circuitry (FIG. 3F). The barrier layer 106 of silicon dioxide is removed by wet or plasma etching (FIG. 3G). Finally, the cantilever 108 (and tip) are released by chemically etching the sacrificial layer 112 (FIG. 3H). The tip die 150 is functionally complete after the last stage of processing.

Embodiments of systems in accordance with the present invention can include tip die comprising cantilever and tip structures oxide fusion bonded with circuitry. The tip die 150 can be bonded with complementary structures to form a storage device as shown in FIG. 1. Methods of bonding the complementary structures are described in detail in U.S. patent application Ser. No. 11/553,421 entitled “Bonded Chip Assembly with a Micro-mover for Microelectromechanical Systems,” incorporated by reference.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A method to fabricate a device including a micro-electro-mechanical system structure and a monolithic integrated circuit, comprising:
using a first wafer as a first substrate;
fabricating the micro-electro-mechanical system structure on the first substrate;
forming a first oxide layer over the micro-electro-mechanical system structure;
using a second wafer as a second substrate;
fabricating the monolithic integrated circuit on the second substrate;
forming a second oxide layer over the monolithic integrated circuit;
arranging the first wafer and the second wafer so that the first oxide layer opposes the second oxide layer;
aligning the micro-electro-mechanical system structure with the monolithic integrated circuit;
contacting the first oxide layer with the second oxide layer; and
bonding the first oxide layer and the second oxide layer.

2. The method of claim 1, further comprising:
planarizing the first oxide layer after forming the first oxide layer over the micro-electro-mechanical system structure;
planarizing the second oxide layer after forming the second oxide layer over the monolithic integrated circuit; and
removing the first substrate after bonding the first oxide layer and the second oxide layer.

3. The method of claim 1, wherein bonding the first oxide layer and the second oxide layer includes fusion bonding the first oxide layer and the second oxide layer.

4. The method of claim 2, further comprising:
forming a via through the micro-electro-mechanical system structure to a conductive interconnect of the monolithic integrated circuit; and forming a conductive material within the via.

5. The method of claim 4, wherein the micro-electro-mechanical system structure is a cantilever having a tip extending from a distal end of the cantilever; and
wherein when the conductive material is formed within the via, the tip is adapted to electrically communicate with the monolithic integrated circuit.

6. The method of claim 5, further comprising:
removing the first oxide layer over a portion of the cantilever including the distal end prior to planarizing the first oxide layer;
forming a sacrificial layer over the portion of the cantilever;
wherein planarizing the first oxide layer includes planarizing the sacrificial layer.

7. The method of claim 6, wherein the sacrificial layer is copper.

8. The method of claim 6, wherein the monolithic integrated circuit is a complementary-metal-oxide semiconductor circuit.

9. The method of claim 6, further comprising:
removing the sacrificial layer so that the distal end of the cantilever is movable relative to the monolithic integrated circuit.

10. The method of claim 1, further comprising:
forming a barrier layer over the first substrate; and
wherein the barrier layer is disposed between the first substrate and the micro-electro-mechanical system structure.

11. The method of claim 10, wherein the barrier layer comprises silicon dioxide.

12. The method of claim 10, wherein fabricating the micro-electro-mechanical system structure on the first substrate further includes:
forming polysilicon over the barrier layer;
removing a portion of the polysilicon layer to define the micro-electro-mechanical system structure.

13. The method of claim 1, wherein fabricating the micro-electro-mechanical system structure on the first substrate further includes:
etching a mold within the first substrate;
forming the barrier layer over the first substrate so that a portion of the barrier layer conforms to the mold;
forming polysilicon over the barrier layer so that a portion of the polysilicon conforms to the mold; and
removing a portion of the polysilicon layer to define the micro-electro-mechanical system structure;
wherein the mold defines a tip of the micro-electro-mechanical system structure.

14. A method to fabricate a tip die to access a media in a probe storage system, the method comprising:
using a first wafer as a first substrate;
fabricating a tip on the first substrate;
depositing a first oxide layer over the tip;
using a second wafer as a second substrate;
fabricating a monolithic integrated circuit on the second substrate;
forming a second oxide layer over the monolithic integrated circuit;
arranging the first wafer and the second wafer so that the first oxide layer opposes the second oxide layer;
aligning the first wafer with the second wafer so that the tip is aligned with the monolithic integrated circuit;
contacting the first oxide layer with the second oxide layer; and
bonding the first oxide layer and the second oxide layer.

15. The method of claim 14, further comprising:
planarizing the first oxide layer after depositing the first oxide layer;
planarizing the second oxide layer after depositing the second oxide layer; and
removing the first substrate after bonding the first oxide layer and the second oxide layer.

16. The method of claim 14, wherein bonding the first oxide layer and the second oxide layer includes fusion bonding the first oxide layer and the second oxide layer.

17. The method of claim 15, further comprising:
fabricating a cantilever on the first substrate;
wherein the tip is associated with a distal end of the cantilever;
etching the first oxide layer to expose the tip and a portion of the cantilever;
depositing a sacrificial layer over the tip and portion of the cantilever;
wherein planarizing the first oxide layer includes planarizing the sacrificial layer; and
etching the sacrificial layer.

18. The method of claim 17, further comprising:
forming a via through the cantilever to a conductive interconnect of the monolithic integrated circuit; and
forming a conductive material within the via;
wherein when the conductive material is formed within the via, the tip is adapted to electrically communicate with the monolithic integrated circuit.

19. The method of claim 17, wherein the sacrificial layer is copper.

20. The method of claim 14, wherein the monolithic integrated circuit is a complementary-metal-oxide semiconductor circuit.

21. The method of claim 14, further comprising:
forming a barrier layer over the first substrate; and
wherein the barrier layer is disposed between the first substrate and the tip.

22. The method of claim 14, wherein the barrier layer comprises silicon dioxide.

23. The method of claim 14, fabricating a tip on the first substrate further includes:
etching a mold within the first substrate;
forming a barrier layer over the first substrate so that a portion of the barrier layer conforms to the mold;
forming polysilicon over the barrier layer so that a portion of the polysilicon conforms to the mold; and
wherein fabricating the cantilever on the first substrate further includes:
forming polysilicon over the barrier layer;
etching a portion of the polysilicon layer to define the cantilever.

24. A method to fabricate a tip die to access a media in a probe storage system, the method comprising:
using a first wafer as a first substrate;
etching a mold within the first substrate to define a tip;
forming a barrier layer over the first substrate so that a portion of the barrier layer conforms to the mold;
forming polysilicon over the barrier layer;
etching a portion of the polysilicon layer to define the cantilever;
depositing a first oxide layer over the cantilever;
etching the first oxide layer to expose a portion of the cantilever;
depositing a sacrificial layer over the portion of the cantilever;
planarizing the first oxide layer and the sacrificial layer;
using a second wafer as a second substrate;
fabricating a monolithic integrated circuit on the second substrate;
forming a second oxide layer over the monolithic integrated circuit;
planarizing the second oxide layer;
arranging the first wafer and the second wafer so that the first oxide layer opposes the second oxide layer;
aligning the first wafer with the second wafer so that the cantilever is aligned with the monolithic integrated circuit;
contacting the first oxide layer with the second oxide layer;
fusion bonding the first oxide layer and the second oxide layer;
etching the first substrate;
forming a via through the cantilever to a conductive interconnect of the monolithic integrated circuit;
forming a conductive material within the via;
wherein when the conductive material is formed within the via, the tip is adapted to electrically communicate with the monolithic integrated circuit;
etching the barrier layer.
